(19) United States
(12) Patent Application Publication
(10) Pub. No.: US 2024/0411970 A1
(43) Pub. Date: Dec. 12, 2024

(54) INTEGRATED CIRCUIT DESIGN USING METADATA

(71) Applicant: SiFive, Inc., Santa Clara, CA (US)

(72) Inventors: Albert Pengju Chen, San Mateo, CA (US); Adam Moshe Izraelevitz, San Mateo, CA (US)

(73) Assignee: SiFive, Inc., Santa Clara, CA (US)

(21) Appl. No.: 18/810,838

(22) Filed: Aug. 21, 2024

Related U.S. Application Data
(63) Continuation of application No. PCT/US2023/010580, filed on Jan. 11, 2023.
(60) Provisional application No. 63/313,893, filed on Feb. 25, 2022.

(51) Int. Cl. G06F 30/327; G06F 8/41

(52) U.S. Cl. CPC G06F 30/327; G06F 8/44

(57) ABSTRACT

An integrated circuit design may be generated for an integrated circuit. The integrated circuit design may include an instance of a module description that describes a functional operation of a module. The integrated circuit design may be encoded in an intermediate representation (IR) data structure. A parameter comprising metadata associated with the instance may be received. A compiler may compile the IR data structure to produce a register-transfer level (RTL) data structure. The RTL data structure may encode a logic description associated with the instance. Compiling the IR data structure may include associating the parameter comprising metadata with the logic description.

### CROSS-REFERENCES TO RELATED APPLICATIONS

This application is a continuation of International Application No. PCT/US2023/010580, filed Jan. 11, 2023, which claims priority to U.S. Provisional Application No. 63/313,893, filed Feb. 25, 2022, the entire contents of which are incorporated herein by reference for all purposes.

### FIELD OF TECHNOLOGY

This disclosure relates generally to integrated circuit design and, more specifically, to integrated circuit design using metadata.

### BACKGROUND

Integrated circuits may be designed and tested in a multi-step process that involves multiple specialized engineers performing a variety of different design and verification tasks on an integrated circuit design. A variety of integrated circuit design tool chains may be used by these engineers to handle different parts of the integrated circuit design workflow of using commercial electronic design automation (EDA) tools.

### BRIEF DESCRIPTION OF THE DRAWINGS

The disclosure is best understood from the following detailed description when read in conjunction with the accompanying drawings. It is emphasized that, according to common practice, the various features of the drawings are not to-scale. On the contrary, the dimensions of the various features are arbitrarily expanded or reduced for clarity.

FIG. 1 is a block diagram of an example of a system for facilitating generation and manufacture of integrated circuits.

FIG. 2 is a block diagram of an example of a system for facilitating generation of integrated circuits.

FIG. 3 is a block diagram of an example of a system for integrated circuit design using metadata.

FIG. 4 is a block diagram of an example of a compiler that may be used for an integrated circuit design using metadata.

FIG. 5 is a block diagram of an example of a compiler compiling an intermediate representation (IR) data structure associated with metadata.

FIG. 6 is a block diagram of an example of a compiler producing a register-transfer level (RTL) data structure associated with metadata.

FIG. 7 is flow chart of a process for integrated circuit design using metadata.

### DETAILED DESCRIPTION

Automated generation of integrated circuit designs permits a configuration of an application specific integrated circuit (ASIC) or a system on a chip (SoC) to be specified in terms of design parameters (or colloquially knobs). A system may then automate the operation of commercial electronic design automation (EDA) tools for design of the integrated circuit using the design parameters.

For example, a system may execute an integrated circuit generator (or simply a generator) to access design parameters and generate an integrated circuit design. In some implementations, the generator may use a hardware description language (HDL) embedded in a general-purpose programming language (e.g., Scala) that supports object-oriented programming and/or functional programming. For example, Chisel, an open source HDL embedded in Scala, a statically typed general purpose programming language that supports both object-oriented programming and functional programming, may be used to generate an integrated circuit design. The generator may include module descriptions that specify input(s), output(s), and/or a description(s) of a functional operation of a module (e.g., a processor core, cache, or the like, which may be represented, for example, by a Scala class).

In a process referred to as elaboration, the generator may execute to generate an integrated circuit design based on the design parameters. The integrated circuit design may include instances of module descriptions with connections being made. For example, the generator may execute constructor code to establish instances of Scala classes, with wired connections between them, as an instantiation of an integrated circuit design. In some implementations, the integrated circuit design may be encoded in an intermediate representation (IR) data structure. The IR data structure may be configured for optimization and/or translation by a compiler to produce a register-transfer level (RTL) data structure. For example, the generator may generate the integrated circuit design as a flexible intermediate representation for register-transfer level (FIRRTL) data structure. The FIRRTL data structure may be compiled by a FIRRTL compiler to produce an RTL data structure.

In a process referred to as compilation, the elaborated integrated circuit design (e.g., the IR data structure) may be compiled to generate an RTL data structure. For example, compiling the integrated circuit design may comprise executing one or more lowering transformations (e.g., compiler transformations that remove high-level constructs) to transform the integrated circuit design to generate the RTL data structure. The RTL data structure may encode a topology of logic associated with the instances of module descriptions implemented in the integrated circuit design (e.g., logic descriptions of the modules, such as the processor cores, caches, and the like). The RTL data structure may be compatible with EDA tools that may be used for functional verification (e.g., simulation analysis), synthesis (e.g., conversion to a gate-level description), placement and routing (e.g., physical design), and/or manufacturing of an integrated circuit (e.g., a processor, a microcontroller, an ASIC, or an SoC). In some implementations, the RTL data structure may comprise Verilog. For example, the integrated circuit design may be compiled using a FIRRTL compiler to generate Verilog.

During the design process, multiple tools may be used to generate the integrated circuit design. For example, Diplomacy, a parameter negotiation framework for generating parameterized protocol implementations, may be used to cross-check requirements of connected devices, negotiate free parameters, and supply final parameter bindings to adapters and endpoints for use in their own hardware generation processes (such as addresses associated with instance). TileLink, a parameterized chip-scale shared-memory interconnect standard, may be used in connection with Diplomacy to specialize the interconnect to different levels of protocol conformance. Chisel, an open source HDL embedded in Scala, may be used in connection with Diplomacy and TileLink to instantiate the integrated circuit design. One or more of these tools (also referred to as “upstream” tools) may produce metadata associated with the integrated circuit design. As discussed herein, metadata is data that provides information about other data (e.g., the integrated circuit design). For example, the integrated circuit design may include instances of module descriptions and connections (e.g., wires or signals) between them (e.g., data). The metadata may include names of the instances and/or the connections, paths to the instances and/or the connections, memory addresses associated with the instances, and/or the like.

When the integrated circuit design is compiled, one or more “downstream” tools (e.g., a simulator) may use the RTL data structure that is produced by the compiler. While the RTL data structure may include useful information for the downstream tools, such as logic descriptions associated with the instances (e.g., the processor cores, caches, and the like), the RTL data structure might not include other information used by such tools. For example, the RTL data structure might not include memory addresses associated with the logic descriptions. As a result, the downstream tools may prepare such information when the RTL data structure is used (e.g., assign a memory address to a logic description), which may be a manual and/or time consuming process. Further, such prepared information may be out of sync with the information being used by upstream tools. For example, an upstream tool (e.g., Diplomacy, TileLink, and/or Chisel) might use a first memory address for an instance, whereas a downstream tool (e.g., a simulator) might use a second memory address for a logic description associated with the instance. This difference could possibly result in a loss of some amount of test coverage which may result, for example, in limited test results from a simulation. Accordingly, there is a need to improve the efficiency of downstream tools when using the RTL data structure. There is also a need to keep downstream tools in closer sync with upstream tools.

Described herein are techniques which permit improving the efficiency of downstream tools and/or keeping downstream tools in closer sync with upstream tools. An integrated circuit generator (or simply a “generator”) may be used to generate an integrated circuit design encoded in an IR data structure. The integrated circuit design may include instances of module descriptions and connections between them (e.g., connections or wires). A module description may specify input(s), output(s), and/or a description(s) of a functional operation of a module (e.g., a processor core, cache, or the like, which may be represented, for example, by a Scala class). The generator used to generate the integrated circuit design may comprise one or more upstream tools (e.g., Diplomacy, TileLink, and/or Chisel). The upstream tools may produce parameters comprising metadata associated with the integrated circuit design (e.g., names of the instances and/or connections, paths to the instances and/or connections, and/or memory addresses associated with the instances). A compiler (e.g., a FIRRTL compiler) may receive the IR data structure and/or the parameters comprising metadata associated with the integrated circuit design. The compiler may compile the IR data structure to produce an RTL data structure. The RTL data structure may encode logic descriptions (e.g., Verilog) associated with the instances of module descriptions implemented in the integrated circuit design. The compiler may also associate the parameters comprising metadata with the RTL data structure (e.g., associate the parameters with logic descriptions and/or nodes in the RTL data structure, corresponding to the instances and/or connections encoded in the IR data structure, respectively). The compiler may update and/or change the parameters based on compiler transformations being executed by the compiler. The compiler may send the parameters comprising metadata (as updated and/or changed) and/or the RTL data structure to downstream tools, such as a simulator. Accordingly, the downstream tools may use the metadata, as updated by the compiler, when using the RTL data structure, such as when simulating the RTL data structure for functional verification.

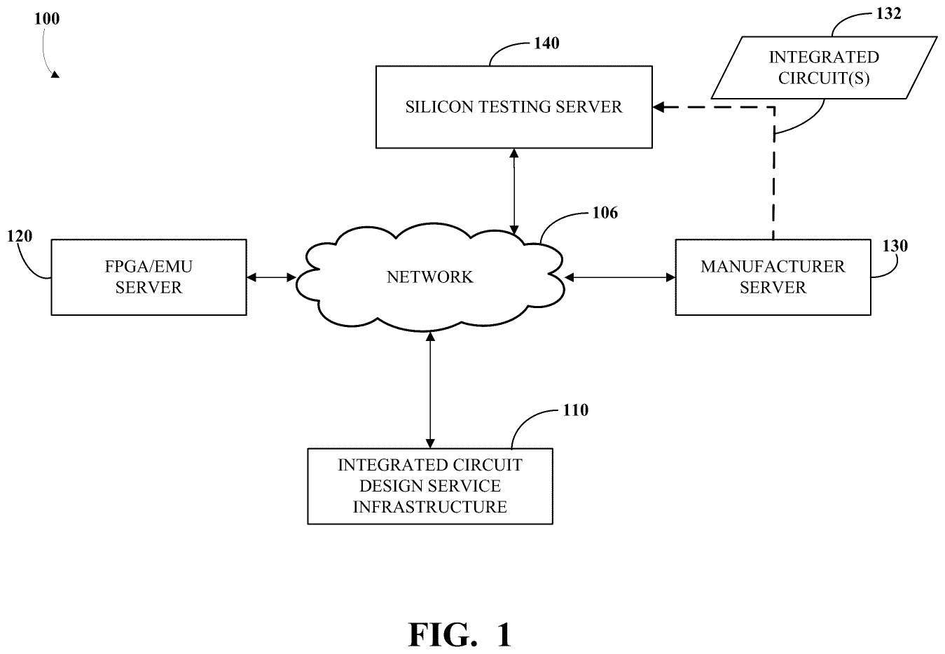

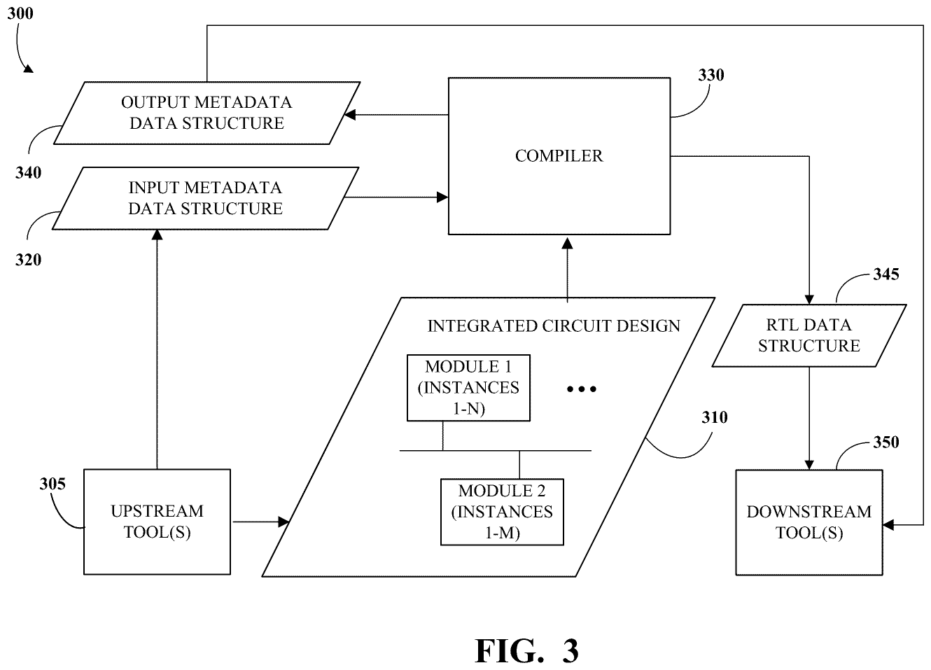

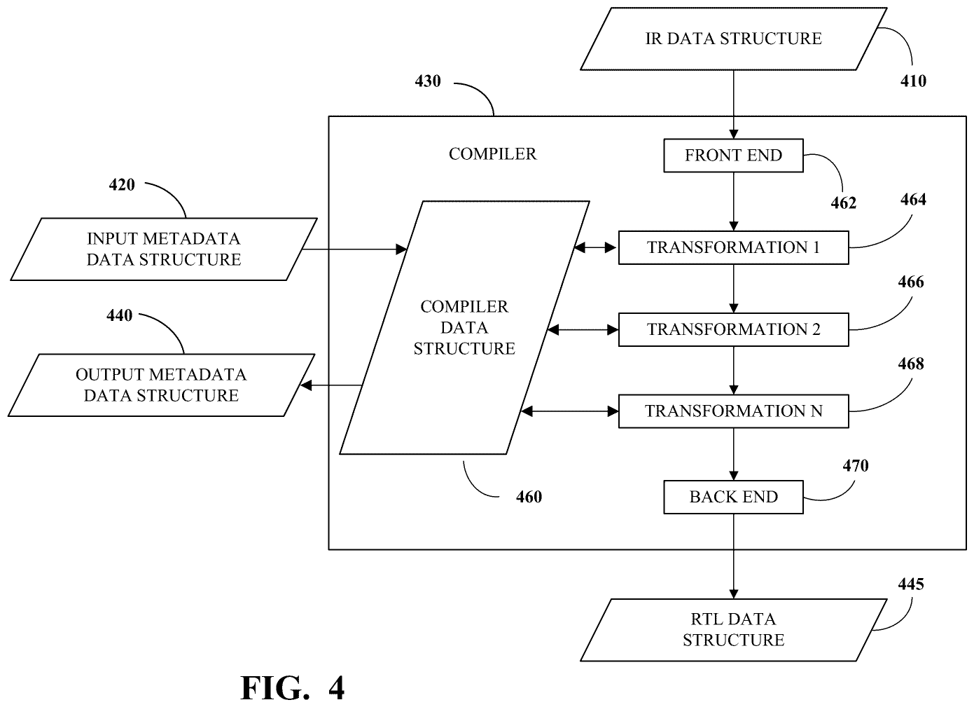

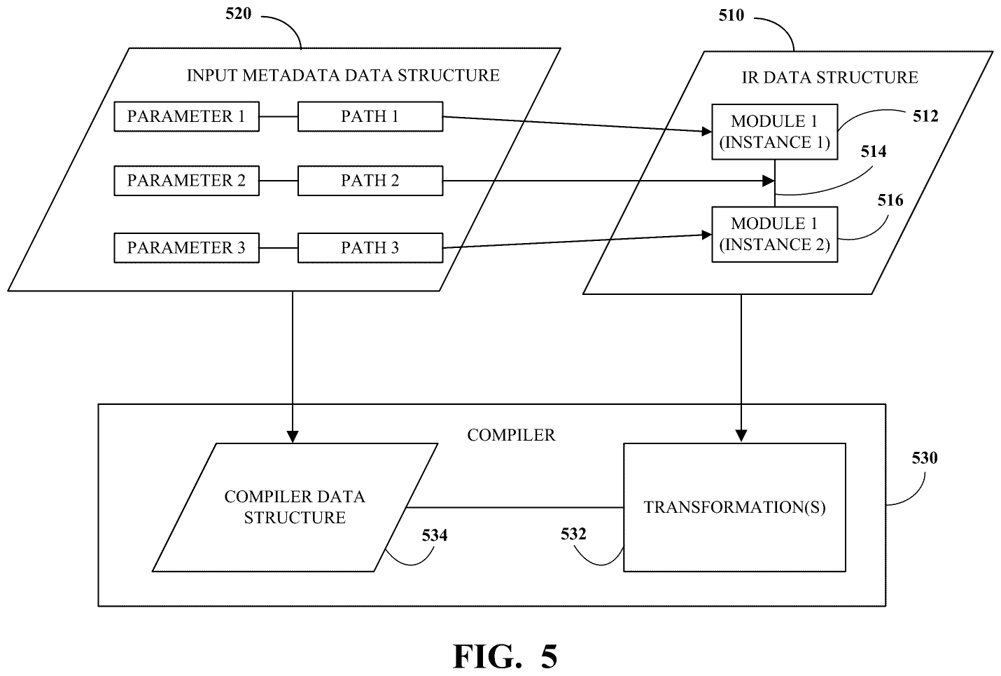

FIG. 1 is a block diagram of an example of a system 100 for generation and manufacture of integrated circuits. The system 100 includes a network 106, an integrated circuit design service infrastructure 110 (e.g., integrated circuit generator), a field programmable gate array (FPGA)/emulator server 120, and a manufacturer server 130. For example, a user may utilize a web client or a scripting application program interface (API) client to command the integrated circuit design service infrastructure 110 to automatically generate an integrated circuit design based on a set of design parameter values selected by the user for one or more template integrated circuit designs. In some implementations, the integrated circuit design service infrastructure 110 may be configured to generate an integrated circuit design like the integrated circuit design 310 shown in FIG. 3, the IR data structure 410 shown in FIG. 4, and/or the IR data structure 510 shown in FIG. 5.

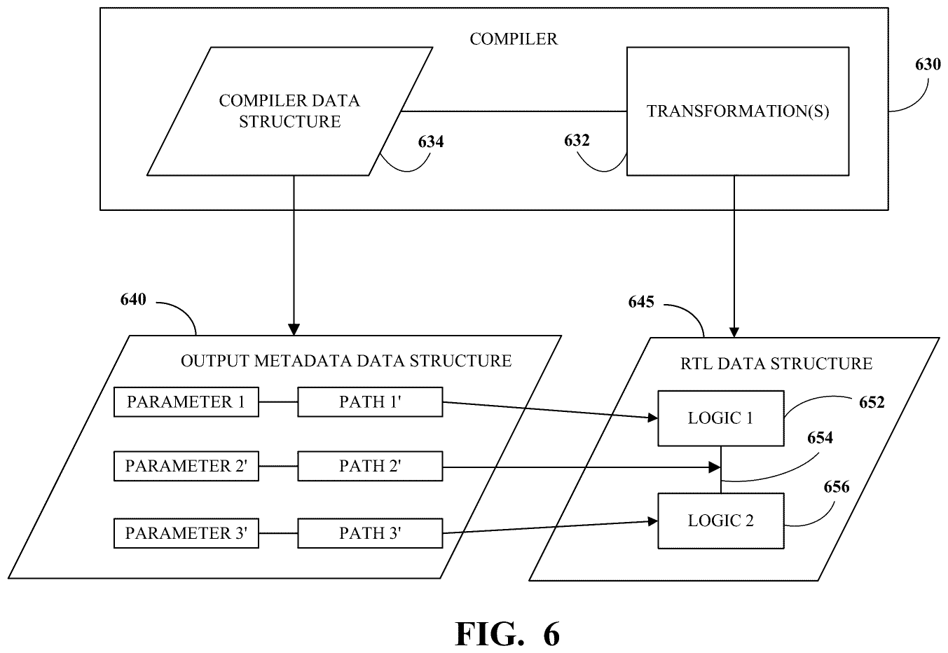

The integrated circuit design service infrastructure 110 may include a register-transfer level (RTL) service module configured to generate an RTL data structure for the integrated circuit based on a design parameters data structure. For example, the RTL service module may be implemented as Scala code. For example, the RTL service module may be implemented using Chisel. For example, the RTL service module may be implemented using flexible intermediate representation for register-transfer level (FIRRTL) and/or a FIRRTL compiler. For example, the RTL service module may be implemented using Diplomacy. For example, the RTL service module may enable a well-designed chip to be automatically developed from a high level set of configuration settings using a mix of Diplomacy, Chisel, and FIRRTL. The RTL service module may take the design parameters data structure (e.g., a java script object notation (JSON) file) as input and output an RTL data structure (e.g., a Verilog file) for the chip. For example, the RTL service module may be used to generate an RTL data structure like the RTL data structure 345 shown in FIG. 3, the RTL data structure 445 shown in FIG. 4, and/or the RTL data structure 645 shown in FIG. 6.

In some implementations, the integrated circuit design service infrastructure 110 may invoke (e.g., via network communications over the network 106) testing of the resulting design that is performed by the FPGA/emulation server 120 that is running one or more FPGAs or other types of hardware or software emulators. For example, the integrated circuit design service infrastructure 110 may invoke a test using a field programmable gate array, programmed based on a field programmable gate array emulation data structure, to obtain an emulation result. The field programmable gate array may be operating on the FPGA/emulation server 120, which may be a cloud server. Test results may be returned by the FPGA/emulation server 120 to the integrated circuit design service infrastructure 110 and relayed in a useful format to the user (e.g., via a web client or a scripting API client).

The integrated circuit design service infrastructure 110 may also facilitate the manufacture of integrated circuits using the integrated circuit design in a manufacturing facility associated with the manufacturer server 130. In some implementations, a physical design specification (e.g., a graphic data system (GDS) file, such as a GDSII file) based on a physical design data structure for the integrated circuit is transmitted to the manufacturer server 130 to invoke manufacturing of the integrated circuit (e.g., using manufacturing equipment of the associated manufacturer). For example, the manufacturer server 130 may host a foundry tape-out website that is configured to receive physical design specifications (e.g., such as a GDSII file or an open artwork system interchange standard (OASIS) file) to schedule or otherwise facilitate fabrication of integrated circuits. In some implementations, the integrated circuit design service infrastructure 110 supports multi-tenancy to allow multiple integrated circuit designs (e.g., from one or more users) to share fixed costs of manufacturing (e.g., reticle/mask generation, and/or shuttles wafer tests). For example, the integrated circuit design service infrastructure 110 may use a fixed package (e.g., a quasi-standardized packaging) that is defined to reduce fixed costs and facilitate sharing of reticle/mask, wafer test, and other fixed manufacturing costs. For example, the physical design specification may include one or more physical designs from one or more respective physical design data structures in order to facilitate multi-tenancy manufacturing.

In response to the transmission of the physical design specification, the manufacturer associated with the manufacturer server 130 may fabricate and/or test integrated circuits based on the integrated circuit design. For example, the associated manufacturer (e.g., a foundry) may perform optical proximity correction (OPC) and similar post-tape-out/pre-production processing, fabricate the integrated circuit(s) 132, update the integrated circuit design service infrastructure 110 (e.g., via communications with a controller or a web application server) periodically or asynchronously on the status of the manufacturing process, perform appropriate testing (e.g., wafer testing), and send to a packaging house for packaging. A packaging house may receive the finished wafers or dice from the manufacturer and test materials and update the integrated circuit design service infrastructure 110 on the status of the packaging and delivery process periodically or asynchronously. In some implementations, status updates may be relayed to the user when the user checks in using the web interface, and/or the controller might email the user that updates are available.

In some implementations, the resulting integrated circuit(s) 132 (e.g., physical chips) are delivered (e.g., via mail) to a silicon testing service provider associated with a silicon testing server 140. In some implementations, the resulting integrated circuit(s) 132 (e.g., physical chips) are installed in a system controlled by the silicon testing server 140 (e.g., a cloud server), making them quickly accessible to be run and tested remotely using network communications to control the operation of the integrated circuit(s) 132. For example, a login to the silicon testing server 140 controlling a manufactured integrated circuit(s) 132 may be sent to the integrated circuit design service infrastructure 110 and relayed to a user (e.g., via a web client). For example, the integrated circuit design service infrastructure 110 may be used to control testing of one or more integrated circuit(s) 132.

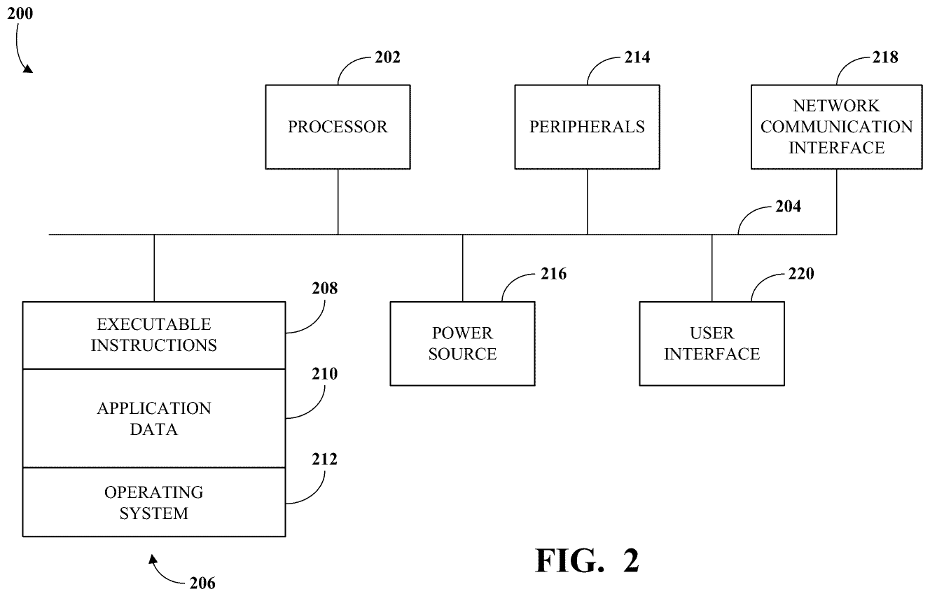

FIG. 2 is a block diagram of an example of a system 200 for facilitating generation of integrated circuits, for facilitating generation of a circuit representation for an integrated circuit, and/or for programming or manufacturing an integrated circuit. The system 200 is an example of an internal configuration of a computing device that may be used to implement the integrated circuit design service infrastructure 110, and/or to generate a file that generates a circuit representation of an integrated circuit design like the integrated circuit design 310 shown in FIG. 3. The system 200 can include components or units, such as a processor 202, a bus 204, a memory 206, peripherals 214, a power source 216, a network communication interface 218, a user interface 220, other suitable components, or a combination thereof.

The processor 202 can be a central processing unit (CPU), such as a microprocessor, and can include single or multiple processors having single or multiple processing cores. Alternatively, the processor 202 can include another type of device, or multiple devices, now existing or hereafter developed, capable of manipulating or processing information. For example, the processor 202 can include multiple processors interconnected in any manner, including hardwired or networked, including wirelessly networked. In some implementations, the operations of the processor 202 can be distributed across multiple physical devices or units that can be coupled directly or across a local area or other suitable type of network. In some implementations, the processor 202 can include a cache, or cache memory, for local storage of operating data or instructions.

The memory 206 can include volatile memory, non-volatile memory, or a combination thereof. For example, the memory 206 can include volatile memory, such as one or more dynamic random access memory (DRAM) modules such as double data rate (DDR) synchronous DRAM (SDRAM), and non-volatile memory, such as a disk drive, a solid-state drive, flash memory, Phase-Change Memory (PCM), or any form of non-volatile memory capable of persistent electronic information storage, such as in the absence of an active power supply. The memory 206 can include another type of device, or multiple devices, now existing or hereafter developed, capable of storing data or instructions for processing by the processor 202. The processor 202 can access or manipulate data in the memory 206 via the bus 204. Although shown as a single block in FIG. 2, the memory 206 can be implemented as multiple units. For example, a system 200 can include volatile memory, such as random access memory (RAM), and persistent memory, such as a hard drive or other storage.

The memory 206 can include executable instructions 208, data, such as application data 210, an operating system 212, or a combination thereof, for immediate access by the processor 202. The executable instructions 208 can include, for example, one or more application programs, which can be loaded or copied, in whole or in part, from non-volatile memory to volatile memory to be executed by the processor 202. The executable instructions 208 can be organized into programmable modules or algorithms, functional programs, codes, code segments, or combinations thereof to perform various functions described herein. For example, the executable instructions 208 can include instructions executable by the processor 202 to cause the system 200 to automatically, in response to a command, generate an integrated circuit design and associated test results based on a design parameters data structure. The application data 210 can include, for example, user files, database catalogs or dictionaries, configuration information or functional programs, such as a web browser, a web server, a database server, or a combination thereof. The operating system 212 can be, for example, Microsoft Windows®, macOS®, or Linux®; an operating system for a small device, such as a smartphone or tablet device; or an operating system for a large device, such as a mainframe computer. The memory 206 can comprise one or more devices and can utilize one or more types of storage, such as solid-state or magnetic storage.

The peripherals 214 can be coupled to the processor 202 via the bus 204. The peripherals 214 can be sensors or detectors, or devices containing any number of sensors or detectors, which can monitor the system 200 itself or the environment around the system 200. For example, a system 200 can contain a temperature sensor for measuring temperatures of components of the system 200, such as the processor 202. Other sensors or detectors can be used with the system 200, as can be contemplated. In some implementations, the power source 216 can be a battery, and the system 200 can operate independently of an external power distribution system. Any of the components of the system 200, such as the peripherals 214 or the power source 216, can communicate with the processor 202 via the bus 204.

The network communication interface 218 can also be coupled to the processor 202 via the bus 204. In some implementations, the network communication interface 218 can comprise one or more transceivers. The network communication interface 218 can, for example, provide a connection or link to a network, such as the network 106 shown in FIG. 1, via a network interface, which can be a wired network interface, such as Ethernet, or a wireless network interface. For example, the system 200 can communicate with other devices via the network communication interface 218 and the network interface using one or more network protocols, such as Ethernet, transmission control protocol (TCP), Internet protocol (IP), power line communication (PLC), Wi-Fi, infrared, general packet radio service (GPRS), global system for mobile communications (GSM), code division multiple access (CDMA), or other suitable protocols.

A user interface 220 can include a display; a positional input device, such as a mouse, touchpad, touchscreen, or the like; a keyboard; or other suitable human or machine interface devices. The user interface 220 can be coupled to the processor 202 via the bus 204. Other interface devices that permit a user to program or otherwise use the system 200 can be provided in addition to or as an alternative to a display. In some implementations, the user interface 220 can include a display, which can be a liquid crystal display (LCD), a cathode-ray tube (CRT), a light emitting diode (LED) display (e.g., an organic light emitting diode (OLED) display), or other suitable display. In some implementations, a client or server can omit the peripherals 214. The operations of the processor 202 can be distributed across multiple clients or servers, which can be coupled directly or across a local area or other suitable type of network. The memory 206 can be distributed across multiple clients or servers, such as network-based memory or memory in multiple clients or servers performing the operations of clients or servers. Although depicted here as a single bus, the bus 204 can be composed of multiple buses, which can be connected to one another through various bridges, controllers, or adapters.

A non-transitory computer readable medium may store a circuit representation that, when processed by a computer, is used to program or manufacture an integrated circuit. For example, the circuit representation may describe the integrated circuit specified using a computer readable syntax. The computer readable syntax may specify the structure or function of the integrated circuit or a combination thereof. In some implementations, the circuit representation may take the form of a hardware description language (HDL) program, a register-transfer level (RTL) data structure, a flexible intermediate representation for register-transfer level (FIRRTL) data structure, a Graphic Design System II (GDSII) data structure, a netlist, or a combination thereof. In some implementations, the integrated circuit may take the form of a field programmable gate array (FPGA), application specific integrated circuit (ASIC), system-on-a-chip (SoC), or some combination thereof. A computer may process the circuit representation in order to program or manufacture an integrated circuit, which may include programming a field programmable gate array (FPGA) or manufacturing an application specific integrated circuit (ASIC) or a system on a chip (SoC). In some implementations, the circuit representation may comprise a file that, when processed by a computer, may generate a new description of the integrated circuit. For example, the circuit representation could be written in a language such as Chisel, an HDL embedded in Scala, a statically typed general purpose programming language that supports both object-oriented programming and functional programming.

In an example, a circuit representation may be a Chisel language program which may be executed by the computer to produce a circuit representation expressed in a FIRRTL data structure. In some implementations, a design flow of processing steps may be utilized to process the circuit representation into one or more intermediate circuit representations followed by a final circuit representation which is then used to program or manufacture an integrated circuit. In one example, a circuit representation in the form of a Chisel program may be stored on a non-transitory computer readable medium and may be processed by a computer to produce a FIRRTL circuit representation. The FIRRTL circuit representation may be processed by a computer to produce an RTL circuit representation. The RTL circuit representation may be processed by the computer to produce a netlist circuit representation. The netlist circuit representation may be processed by the computer to produce a GDSII circuit representation. The GDSII circuit representation may be processed by the computer to produce the integrated circuit.

In another example, a circuit representation in the form of Verilog or VHDL may be stored on a non-transitory computer readable medium and may be processed by a computer to produce an RTL circuit representation. The RTL circuit representation may be processed by the computer to produce a netlist circuit representation. The netlist circuit representation may be processed by the computer to produce a GDSII circuit representation. The GDSII circuit representation may be processed by the computer to produce the integrated circuit. The foregoing steps may be executed by the same computer, different computers, or some combination thereof, depending on the implementation.

FIG. 3 is a block diagram of an example of a system 300 for integrated circuit design using metadata. The system 300 may include upstream tool(s) 305, an integrated circuit design 310, a compiler 330, and downstream tool(s) 350. An integrated circuit generator comprising the upstream tool(s) 305 may be used to generate the integrated circuit design 310. For example, the integrated circuit design service infrastructure 110 shown in FIG. 1, which may comprise the upstream tool(s) 305, may be used to generate the integrated circuit design 310. In some implementations, the upstream tool(s) 305 may include Diplomacy, TileLink, and/or Chisel. For example, Diplomacy, a parameter negotiation framework for generating parameterized protocol implementations, may be used to cross-check requirements of connected devices, negotiate free parameters, and supply final parameter bindings to adapters and endpoints for use in the integrated circuit design 310 (such as addresses associated with instance). TileLink, a parameterized chip-scale shared-memory interconnect standard, may be used in connection with Diplomacy to specialize the interconnect to different levels of protocol conformance for use in the integrated circuit design 310. Chisel, an open source HDL embedded in Scala, may be used in connection with Diplomacy and TileLink to instantiate the integrated circuit design 310. The integrated circuit design 310 may be encoded in an IR data structure (e.g., a FIRRTL data structure).

The integrated circuit design 310 may include module descriptions. A module description may describe a functional operation of a module (e.g., a processor core or a cache). The integrated circuit design 310 may be executed so that it is elaborated (e.g., expanded) to include instances of the module descriptions. For example, the integrated circuit design 310 may be expanded to include instances 1 through N of module description 1, and instances 1 through M of module description 2. The module descriptions can be manipulated using functions of a general-purpose programming language (e.g., embedded in Scala). Interfaces to the module descriptions can be encoded in types associated with the general-purpose programming language.

An instance of a module description may include input(s) and/or output(s) and may be representative of hardware to be implemented in the integrated circuit design 310 (e.g., the processor core or the cache). For example, module description 1 may correspond to a processor core, and instances 1 through N of module description 1 may correspond to N instances of the processor core. Additionally, module description 2 may correspond to a cache, and instances 1 through M of module description 2 may correspond to M instances of the cache. Additionally, one or more of the instances may be configured to be in communication with one another, such as via a system bus. Thus, the integrated circuit design 310 may include instances of module descriptions and connections between them (e.g., connections or wires).

During the design process, one or more of the upstream tool(s) 305 may produce one or more parameters comprising metadata associated with the integrated circuit design 310 (such as metadata associated with the instances, such as instances 1 through N of module description 1, instances 1 through M of module description 2, and/or connections between them). For example, the upstream tool(s) 305 may produce parameters such as names of the instances and/or connections (e.g., names of the instances 1 through N, names of the instances 1 through M, and/or names of the connections between them), paths to the instances and/or connections in the integrated circuit design 310 (e.g., paths to the instances 1 through N, paths to the instances 1 through M, and/or paths to the connections between them), and/or memory addresses associated with the instances (e.g., memory addresses mapped to the instances 1 through N and/or memory addresses mapped to the instances 1 through M, such as for loading programs into memory for functional verification). The parameters may be collected from the upstream tool(s) 305 and may be stored in a data structure, such as an input metadata data structure 320. In some implementations, the input metadata data structure 320 may comprise a text file comprising the parameters, such as a JSON file, which could be a text file in a serialized data format.

The compiler 330 may receive the integrated circuit design 310 (e.g., the IR data structure) and/or the parameters comprising metadata (e.g., the input metadata data structure 320). The compiler 330 may compile the integrated circuit design 310 (e.g., execute one or more compiler transformations) to produce an RTL data structure 345. The RTL data structure 345 may encode logic descriptions and/or nodes corresponding to the instances and/or connections encoded in the integrated circuit design 310, respectively. For example, the RTL data structure 345 may include logic descriptions corresponding to the instances 1 through N of module description 1 and the instances 1 through M of module description 2 and may include nodes corresponding to the connections between the instances 1 through N and the instances 1 through M. In some implementations, the compiler 330 may be a FIRRTL compiler that compiles the integrated circuit design 310 to generate the RTL data structure 345. In some implementations, the compiler 330 may compile the integrated circuit design 310 to generate the RTL data structure 345 comprising Verilog.

The compiler 330 may associate the parameters comprising metadata (e.g., from the input metadata data structure 320) with the RTL data structure 345 (e.g., associate the parameters with the logic descriptions and/or nodes in the RTL data structure 345, corresponding to the instances and/or connections encoded in the IR data structure, respectively), such as when compiling the integrated circuit design 310. The compiler 330 may update and/or change the parameters based on compiler transformations being executed by the compiler 330. The compiler 330 may use a compiler data structure to update and/or change the parameters, such as an abstract syntax tree or table. The compiler 330 may store the parameters, including as updated and/or changed, in a data structure, such as an output metadata data structure 340. In some implementations, the output metadata data structure 340 may comprise a text file comprising the parameters, such as a JSON file, which could be a text file in a serialized data format.

The compiler 330 may send the parameters (e.g., the output metadata data structure 340) and/or the RTL data structure 345 to downstream tool(s) 350 (e.g., a simulator). The downstream tool(s) 350 may use the metadata, as updated by the compiler 330, when using the RTL data structure 345, such as when simulating the RTL data structure 345 for functional verification. For example, the downstream tool(s) 350 may reference the output metadata data structure 340 to determine memory addresses that should be used for logic descriptions in the RTL data structure 345 (e.g., corresponding to the instances encoded in the integrated circuit design 310). This may permit improving the efficiency of the downstream tool(s) 350, such as by using metadata from the output metadata data structure 340 as opposed to preparing such information anew, which may be a manual and/or time consuming process. This may also permit keeping downstream tool(s) 350 in closer sync with the upstream tool(s) 305, such as by using metadata in the downstream tool(s) 350 that may correspond to metadata used by the upstream tool(s) 305.

In some implementations, the downstream tool(s) 350 may apply the metadata to build an IP-XACT description (e.g., an extensible markup language (XML) format model that defines a re-usable electronic circuit design,). For example, the parameters comprising metadata could include register maps, addresses of address blocks, port names, mappings to logical TileLink names, which may be used to build the IP-XACT model. In some implementations, the downstream tool(s) 350 may apply the metadata to configure test harnesses for functional verification (e.g., simulation). For example, the parameters comprising metadata could include memory addresses to load programs into memories.

FIG. 4 is a block diagram of an example of a compiler 430 that may be used for an integrated circuit design using metadata. The compiler 430 may receive an IR data structure 410 and an input metadata data structure 420. The compiler 430 may execute to produce an RTL data structure 445 and an output metadata data structure 440 (e.g., based on the IR data structure 410 and the input metadata data structure 420). For example, the compiler 430 could be like the compiler 330 shown in FIG. 3. The compiler 430 could receive an IR data structure (e.g., the IR data structure 410) that is an encoding of an integrated circuit design like the integrated circuit design 310 shown in FIG. 3. The compiler 430 could receive an input metadata data structure (e.g., the input metadata data structure 420) like the input metadata data structure 320 shown in FIG. 3. The compiler 430 could produce an RTL data structure (e.g., the RTL data structure 445) and an output metadata data structure (e.g., the output metadata data structure 440) like the RTL data structure 345 and the output metadata data structure 340 shown in FIG. 3, respectively. In some implementations, the integrated circuit design service infrastructure 110 shown in FIG. 1 could use the compiler 430 to generate the RTL data structure 445.

The compiler 430 may include various software components, such as a compiler data structure 460, a compiler front end 462, one or more compiler transformations, such as compiler transformations 464, 466, and 468, and a compiler back end 470. The compiler 430 may receive metadata associated with an integrated circuit design (e.g., metadata associated with the IR data structure 410, such as metadata associated with instances and/or connections in the IR data structure 410) via the input metadata data structure 420. The compiler 430 may prepare the compiler data structure 460 based on the metadata received via the input metadata data structure 420. In some implementations, the compiler 430 may receive the input metadata data structure 420 as a text file comprising the parameters, such as a JSON file. For example, the input metadata data structure 420 could be a text file received in a serialized data format. The compiler 430 may de-serialize the input metadata data structure 420 to construct the compiler data structure 460. In some implementations, the compiler data structure 460 could comprise an abstract syntax tree prepared by the compiler 430 from the input metadata data structure 420. In some implementations, the compiler data structure 460 could comprise a table. The compiler 430 may associate the parameters comprising metadata (e.g., from the input metadata data structure 420) with instances and/or connections in the IR data structure 410. In some implementations, the compiler 430 may represent the parameters, associated with the instances and/or connections in the IR data structure 410, as nodes in the abstract syntax tree.

In some implementations, the compiler 430 may receive the IR data structure 410 via the compiler front end 462. The compiler front end 462 may parse the IR data structure 410 (e.g., encoded in a specific format) into a compiler-specific format (e.g., FIRRTL, if the IR data structure 410 is not already a FIRRTL data structure). The IR data structure 410, parsed into the compiler-specific format, may be provided to the one or more compiler transformations, such as the compiler transformations 464, 466, and 468. The one or more compiler transformations may produce an output, in the compiler-specific format, to the compiler back end 470. The compiler back end 470 may convert the output into a target format (e.g., Verilog) to produce the RTL data structure 445.

The compiler transformations (e.g., the compiler transformations 464, 466, and 468) may comprise one or more lowering transformations (e.g., compiler transformations that remove high-level constructs) that may be executed by the compiler 430. The compiler transformations may transform the IR data structure 410 to produce the RTL data structure 445. Executing a given compiler transformation (e.g., the compiler transformation 464) could comprise one or more changes that affect a visible part of the integrated circuit design (e.g., visible to downstream tool(s) that use the RTL data structure 445), such as changing a name associated with an instance, changing a name associated with a connection to an instance, indicating a removal of a connection associated with an instance, and/or indicating a removal of an instance. For example, executing a compiler transformation could comprise propagating a constant (e.g., associating a connection with a constant value, such as “0,” as opposed to associating the connection to the instance, such as when the connection is determined to be driven by the instance to the constant value), eliminating “dead” code (e.g., removing a connection from the integrated circuit design when the connection is determined to no longer exists), and/or the like. Such compiler transformations may affect a visible part of the integrated circuit design (e.g., visible to downstream tool(s) that use the RTL data structure 445). Thus, executing a given compiler transformation (such as the compiler transformation 464) may include an update step. The update step may occur at the end of executing the compiler transformation. The update step may include updating and/or changing the parameters comprising metadata (e.g., in the compiler data structure 460, such as the parameters represented as nodes in the abstract syntax tree) based on changes made by the compiler transformation (such as changing a name associated with an instance, changing a name associated with a connection to an instance, indicating a removal of a connection associated with an instance, and/or indicating a removal of an instance). Accordingly, the compiler 430 may execute the compiler transformations (e.g., the compiler transformations 464, 466, and 468) to update and/or change the parameters in the compiler data structure 460 (such as updating the nodes in the abstract syntax tree) to associate the parameters with the RTL data structure 445 (e.g., to associate the parameters with logic descriptions and/or nodes in the RTL data structure, corresponding to instances and/or connections encoded in the IR data structure, respectively).

After compiling the IR data structure 410, the compiler 430 may produce the RTL data structure 445. Further, the compiler 430 may store the parameters, including as updated and/or changed by the compiler transformations to produce the RTL data structure 445, in the output metadata data structure 440. In some implementations, the compiler 430 may store the output metadata data structure 440 as a text file comprising the parameters (as updated and/or changed), such as a JSON file. For example, the output metadata data structure 440 could be a text file prepared in a serialized data format. The compiler 430 may serialize the compiler data structure 460 to construct the output metadata data structure 440. The compiler 430 may send the output metadata data structure 440 and/or the RTL data structure 445 to downstream tool(s) (e.g., downstream tool(s) 350 shown in FIG. 3), such as a simulator.

FIG. 5 is a block diagram of an example of a compiler 530 compiling an IR data structure 510 associated with metadata. The compiler 530 may receive an IR data structure 510 and an input metadata data structure 520. The compiler 530 may execute to produce an RTL data structure and an output metadata data structure (e.g., the RTL data structure 645 and the output metadata data structure 640 shown in FIG. 6, respectively). The compiler 530 may produce the RTL data structure and the output metadata data structure based on the IR data structure 510 and the input metadata data structure 520. For example, the compiler 530 could be like the compiler 330 shown in FIG. 3. The compiler 530 could receive the IR data structure 510 that is an encoding of an integrated circuit design like the integrated circuit design 310 shown in FIG. 3. The compiler 530 could receive the input metadata data structure 520 like the input metadata data structure 320 shown in FIG. 3. The compiler 530 could produce an RTL data structure and an output metadata data structure like the RTL data structure 345 and the output metadata data structure 340 shown in FIG. 3, respectively. In some implementations, the integrated circuit design service infrastructure 110 shown in FIG. 1 could use the compiler 530 to generate an RTL data structure.

The input metadata data structure 520 could include parameters comprising metadata, such as “Parameter 1,” “Parameter 2,” and “Parameter 3” (e.g., names of instances, names of connections, and/or memory addresses associated with instances, that are associated with the IR data structure 510) and “Path 1,” “Path 2,” and “Path 3” (e.g., paths to the instances and/or connections encoded in the IR data structure 510, embedded as targets in the input metadata data structure 520). As a result, the metadata may be mapped or linked to the associated instances and/or the connections instantiated in the IR data structure 510. For example, the parameters (e.g., as “Parameter 1,” “Parameter 2,” and “Parameter 3”) may be associated with the instances and/or connections in the IR data structure 510 via the paths in the input metadata data structure 520 (e.g., Path 1,” “Path 2,” and “Path 3”). For example, Parameter 1 (e.g., a memory address) may be associated with instance 512 (e.g., a processor core) via Path 1 (e.g., a first instance path); Parameter 2 (e.g., a connection name) may be associated with connection 514 (e.g., a connection between instance 512 and instance 516, such as an internal bus signal or wire) via Path 2 (e.g., a connection path); and Parameter 3 (e.g., an instance name) may be associated with instance 516 (e.g., a cache) via Path 3 (e.g., a second instance path). The input metadata data structure 520 could be a serialized text file.

The compiler 530 may receive the IR data structure 510 and the input metadata data structure 520 (e.g., the parameters comprising metadata associated with the IR data structure 510). The compiler 530 may prepare a compiler data structure 534 based on the input metadata data structure 520, such as an abstract syntax tree or table. The compiler 530 may execute one or more compiler transformations 532 to compile the IR data structure 510 to produce the RTL data structure (e.g., for downstream tool(s), such as the downstream tool(s) 350 shown in FIG. 3, such as a simulator). The compiler 530 may also maintain the mapping or linking of metadata associated with the design, including with updates and/or changes to one or more of the parameters comprising metadata in the compiler data structure 534, such as when executing the compiler transformations 532. For example, the compiler 530 may update and/or change the parameters in the compiler data structure 534 to associate the parameters with the RTL data structure (e.g., logic descriptions and/or nodes in the RTL data structure, corresponding to the instances and/or connections encoded in the IR data structure, respectively). The compiler 530 may prepare an output metadata data structure based on the compiler data structure 534 (e.g., for downstream tool(s), such as the downstream tool(s) 350 shown in FIG. 3, such as the simulator). As a result, the metadata may be updated to be mapped or linked to logic descriptions and/or nodes in the RTL data structure that correspond to the instances and/or the connections in the IR data structure 510. For example, the compiler 530 may prepare an output metadata data structure, such as “Parameter 1,” “Parameter 2′,” and “Parameter 3′” (e.g., names of instances, names of connections, and/or memory addresses associated with instances, some of which having changed, like Parameter 2 and Parameter 3 having changed as denoted by a prime symbol) with “Path 1′,” “Path 2′,” and “Path 3′” (e.g., paths to the logic descriptions and/or nodes in the RTL data structure, corresponding to the instances and/or connections encoded in the IR data structure 510, respectively, having changed to the RTL data structure as denoted by a prime symbol). For example, like an output metadata data structure 640 shown in FIG. 6, the output metadata data structure could include Parameter 1 (e.g., the memory address, unchanged from the input metadata data structure 520) associated with a first logic description (e.g., corresponding to the instance 512 encoded in the IR data structure 510, the processor core) via Path 1′ (e.g., a first logic description path); Parameter 2′ (e.g., an updated connection name, changed from the input metadata data structure 520) associated with a node (e.g., corresponding to the connection 514 encoded in the IR data structure 510) via Path 2′ (e.g., a node path); and Parameter 3′ (e.g., an updated instance name, changed from the input metadata data structure 520) associated with a second logic description (e.g., corresponding to the instance 516 encoded in the IR data structure 510, the cache) via Path 3′ (e.g., a second logic description path). The output metadata data structure could be a serialized text file.

FIG. 6 is a block diagram of an example of a compiler 630 producing an RTL data structure 645 associated with metadata. The compiler 630 may receive an IR data structure and an input metadata data structure (e.g., the IR data structure 510 and the input metadata data structure 520 shown in FIG. 5, respectively). The compiler 630 may execute to produce an RTL data structure 645 and an output metadata data structure 640. The compiler 630 may produce the RTL data structure 645 and the output metadata data structure 640 based on the IR data structure and the input metadata data structure. For example, the compiler 630 could be like the compiler 330 shown in FIG. 3. The compiler 630 could receive an IR data structure that is an encoding of an integrated circuit design like the integrated circuit design 310 shown in FIG. 3. The compiler 630 could receive an input metadata data structure like the input metadata data structure 320 shown in FIG. 3. The compiler 630 could produce the RTL data structure 645 and the output metadata data structure 640 like the RTL data structure 345 and the output metadata data structure 340 shown in FIG. 3, respectively. In some implementations, the integrated circuit design service infrastructure 110 shown in FIG. 1 could use the compiler 630 to generate an RTL data structure, such as the RTL data structure 645.

For example, like the input metadata data structure 520 shown in FIG. 5, the input metadata data structure could include parameters comprising metadata, such as “Parameter 1,” “Parameter 2,” and “Parameter 3” (e.g., names of instances, names of connections, and/or memory addresses associated with instances, associated with the IR data structure) and “Path 1,” “Path 2,” and “Path 3” (e.g., paths to the instances and/or connections in the IR data structure, embedded as targets in the input metadata data structure). As a result, the metadata may be mapped or linked to the associated instances and/or the connections instantiated in the IR data structure. For example, the parameters (e.g., as “Parameter 1,” “Parameter 2,” and “Parameter 3”) may be associated with the instances and/or connections encoded in the IR data structure via the paths in the input metadata data structure (e.g., Path 1,” “Path 2,” and “Path 3”). For example, Parameter 1 (e.g., a memory address) may be associated with a first instance (e.g., a processor core) via Path 1 (e.g., a first instance path); Parameter 2 (e.g., a connection name) may be associated with a connection (e.g., a connection between the first instance and a second instance, such as an internal bus signal or wire) via Path 2 (e.g., a connection path); and Parameter 3 (e.g., an instance name) may be associated with a second instance (e.g., a cache) via Path 3 (e.g., a second instance path). The input metadata data structure could be a serialized text file.

The compiler 630 may receive the IR data structure and the input metadata data structure (e.g., the parameters comprising metadata associated with the IR data structure). The compiler 630 may prepare a compiler data structure 634 based on the input metadata data structure, such as an abstract syntax tree or table. The compiler 630 may execute one or more compiler transformations 632 to compile the IR data structure to produce the RTL data structure 645 (e.g., for downstream tool(s), such as the downstream tool(s) 350 shown in FIG. 3, such as a simulator). The compiler 630 may also maintain the mapping or linking of metadata associated with the design, including with updates and/or changes to one or more of the parameters comprising metadata in the compiler data structure 634, such as when executing the compiler transformations 632. For example, the compiler 630 may update and/or change the parameters in the compiler data structure 634 to associate the parameters with the RTL data structure 645 (e.g., to associate the parameters with logic descriptions and/or nodes in the RTL data structure 645, corresponding to instances and/or connections encoded in the IR data structure, respectively). The compiler 630 may prepare an output metadata data structure 640 based on the compiler data structure 634 (e.g., for downstream tool(s), such as the downstream tool(s) 350 shown in FIG. 3, such as the simulator). As a result, the metadata may be updated to be mapped or linked to logic descriptions and/or nodes in the RTL data structure 645 that correspond to the instances and/or the connections in the IR data structure. For example, the compiler 630 may prepare an output metadata data structure 640, such as “Parameter 1,” “Parameter 2′,” and “Parameter 3′” (e.g., names of instances, names of connections, and/or memory addresses associated with instances, some of which having changed, like Parameter 2 and Parameter 3 having changed as denoted by a prime symbol) with “Path 1′,” “Path 2′,” and “Path 3′” (e.g., paths to the logic descriptions and/or nodes in the RTL data structure 645, corresponding to the instances and/or connections encoded in the IR data structure, respectively, having changed to the RTL data structure 645 as denoted by a prime symbol). For example, Parameter 1 (e.g., the memory address, unchanged from the input metadata data structure) associated with a first logic description 652 (e.g., corresponding to the first instance encoded in the IR data structure, the processor core) (e.g., the instance 512) via Path 1′ (e.g., a first logic description path); Parameter 2′ (e.g., an updated connection name, changed from the input metadata data structure) associated with a node 654 (e.g., corresponding to the connection encoded in the IR data structure) (e.g., the connection 514) via Path 2′ (e.g., a node path); and Parameter 3′ (e.g., an updated instance name, changed from the input metadata data structure) associated with a second logic description 656 (e.g., corresponding to the second instance encoded in the IR data structure, the cache) (e.g., the instance 516) via Path 3′ (e.g., a second logic description path). The output metadata data structure 640 could be a serialized text file.

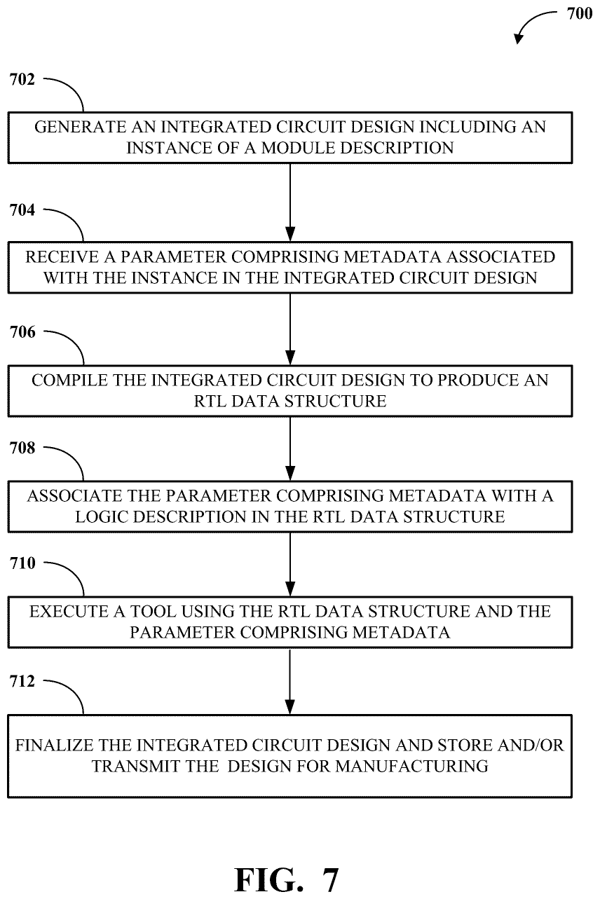

FIG. 7 is flow chart of a process 700 for integrated circuit design using metadata. The process 700 includes generating 702 an integrated circuit design including an instance of a module description; receiving 704 a parameter comprising metadata associated with the instance in the integrated circuit design; compiling 706 the integrated circuit design to generate an RTL data structure; associating 708 the parameter comprising metadata with a logic description in the RTL data structure; executing 710 a tool using the RTL data structure and the parameter comprising metadata; and storing and/or transmitting 712 the integrated circuit design. For example, the process 700 may be implemented using the system 100 shown in FIG. 1, the system 200 shown in FIG. 2, and/or the system 300 shown in FIG. 3.

The process 700 may include generating 702 an integrated circuit design (e.g., the integrated circuit design 310, which may be encoded in an IR data structure like the IR data structure 410 and/or the IR data structure 510) including one or more instances of one or more module descriptions. For example, the integrated circuit design service infrastructure 110 shown in FIG. 1 may be used to generate the integrated circuit design. A generator comprising one or more upstream tool(s) (e.g., Diplomacy, TileLink, and/or Chisel) (e.g., the upstream tool(s) 305) may be used to generate the integrated circuit design. The generator may use an HDL embedded in a general-purpose programming language (e.g., Scala) that supports object-oriented programming and/or functional programming. The generator may produce the integrated circuit design to include instances of module descriptions that may be representative of hardware to be implemented in the integrated circuit design (e.g., processors cores, caches, and the like). The instances may include input(s) and/or output(s) with connections being made between them. The generator may also produce parameters comprising metadata associated with the integrated circuit design (e.g., names of the instances and/or connections, paths to the instances and/or connections, and/or memory addresses associated with the instances). For example, Chisel, Diplomacy and/or TileLink may produce parameters comprising metadata associated with the integrated circuit design. The integrated circuit design may be encoded in an IR data structure (e.g., a FIRRTL data structure).

The process 700 may also include receiving 704 a parameter comprising metadata associated with an instance of a module description implemented in the integrated circuit design. For example, parameters comprising metadata may be collected from upstream tool(s) (e.g., the upstream tool(s) 305) in an input metadata data structure (e.g., the input metadata data structure 320, the input metadata data structure 420, or the input metadata data structure 520). The parameters comprising metadata may be stored in a data structure such as a text file (e.g., a JSON file) in a serialized data format. A compiler (e.g., the compiler 330, the compiler 430, the compiler 530, or the compiler 630) may receive the integrated circuit design (e.g., an IR data structure) and/or the parameters comprising metadata (e.g., the input metadata data structure 320, the input metadata data structure 420, the input metadata data structure 520). The parameters comprising metadata may include metadata associated with the integrated circuit design, such as the names of the instances and/or connections, paths to the instances and/or connections, and/or memory addresses associated with the instances. The compiler may prepare a compiler data structure (e.g., the compiler data structure 460), such as an abstract syntax tree, based on the parameters comprising metadata.

The process 700 may also include compiling 706 the integrated circuit design to generate an RTL data structure (e.g., the RTL data structure 345, the RTL data structure 445, or the RTL data structure 645). For example, the compiler may compile the IR data structure (e.g., associated with the integrated circuit design) to produce the RTL data structure. The RTL data structure may encode logic descriptions associated with the instances of module descriptions implemented in the integrated circuit design (e.g., Verilog). Compiling the integrated circuit design may include executing one or more compiler transformations that affect a visible part of the integrated circuit design (e.g., visible to downstream tool(s) that use the RTL data structure), such as changing a name associated with an instance, changing a name associated with a connection to an instance, indicating a removal of a connection associated with an instance, and/or indicating a removal of an instance.

The process 700 may also include associating 708 the parameter comprising metadata with a logic description implemented in the RTL data structure. The compiler may associate the parameters comprising metadata with the RTL data structure (e.g., logic descriptions and/or nodes in the RTL data structure, associated with the instances and/or connections in the IR data structure, respectively) when compiling the integrated circuit design. The compiler may update and/or change the parameters based on compiler transformations being executed by the compiler. For example, executing a compiler transformation could comprise propagating a constant, eliminating “dead” code, and/or the like. Such a compiler transformation may affect a visible part of the integrated circuit design (e.g., visible to downstream tool(s) that use the RTL data structure). Thus, executing a given compiler transformation may include an update step. The update step may occur at the end of executing the compiler transformation. The update step may include updating and/or changing the parameters comprising metadata (e.g., in the compiler data structure, such as parameters represented as nodes in an abstract syntax tree) based on changes made by the compiler transformation (such as changing a name associated with an instance, changing a name associated with a connection to an instance, indicating a removal of a connection associated with an instance, and/or indicating a removal of an instance). Accordingly, the compiler may execute the compiler transformations (e.g., the compiler transformations 464, 466, and 468) to update and/or change the parameters in the compiler data structure (e.g., update the nodes in the abstract syntax tree) to associate the parameters with the RTL data structure (e.g., to associate with logic descriptions and/or nodes in the RTL data structure, corresponding to instances and/or connections encoded in the IR data structure, respectively).

The process 700 may also include executing 710 a tool using the RTL data structure and the parameter comprising metadata. For example, the compiler may store the parameters, including as updated and/or changed by the compiler transformations to produce the RTL data structure, via an output metadata data structure (e.g., the output metadata data structure 440). The parameters comprising metadata may be stored in a data structure such as a text file (e.g., a JSON file) in a serialized data format. The compiler may serialize the compiler data structure to construct the output metadata data structure. The compiler may send the output metadata data structure and/or the RTL data structure to the downstream tool(s). Accordingly, the downstream tools may use the metadata, as updated by the compiler, when using the RTL data structure, such as for functional verification. In some implementations, the downstream tool(s) may apply the metadata to build an IP-XACT model. For example, the parameters comprising metadata could include register maps, addresses of address blocks, port names, mappings to logical TileLink names, which may be used to build the IP-XACT model. In some implementations, the downstream tool(s) may apply the metadata to configure test harnesses for functional verification (e.g., simulation). For example, the parameters comprising metadata could include memory addresses to load programs into memories.

The process 700 may also include storing and/or transmitting 712 the integrated circuit design. The integrated circuit design may be stored for use in subsequent steps, such as synthesis, placement and routing, implementation of clock trees, and/or simulation analysis. Additionally, the integrated circuit design may be transmitted for manufacturing of an integrated circuit, such as a SoC.

In a first aspect, the subject matter described in this specification can be embodied in a method that includes: generating an integrated circuit design for an integrated circuit, wherein the integrated circuit design includes an instance of a module description that describes a functional operation of a module, and wherein the integrated circuit design is encoded in an IR data structure; receiving a parameter comprising metadata associated with the instance; and compiling the IR data structure to produce an RTL data structure, wherein the RTL data structure encodes a logic description associated with the instance, and wherein compiling the IR data structure comprises associating the parameter with the logic description. In some implementations, compiling the IR data structure may include executing a compiler transformation and changing the parameter based on the compiler transformation. In some implementations, the parameter may be at least one of: a name associated with the instance; a name associated with a connection to the instance; or a memory address associated with the instance. In some implementations, the method may include receiving an instance path associated with the parameter and using the instance path to associate the parameter with the logic description. In some implementations, the method may include changing the parameter when compiling the IR data structure by at least one of: changing a name associated with the instance; changing a name associated with a connection to the instance; or indicating a removal of a connection associated with the instance. In some implementations, the parameter may be a first parameter, the integrated circuit design may include a connection to the instance, the RTL data structure may encode a node associated with the connection, and the method may include receiving a second parameter comprising metadata associated with the connection, wherein compiling the IR data structure includes associating the second parameter with the node. In some implementations, compiling the IR data structure may include receiving a text file comprising the parameter associated with the instance and preparing an abstract syntax tree from the text file, wherein the abstract syntax tree is updated to associate the parameter with the logic description. In some implementations, compiling the IR data structure may include preparing an abstract syntax tree, wherein the abstract syntax tree associates the parameter with the instance, and wherein the abstract syntax tree is updated to associate the parameter with the logic description, and producing a text file from the abstract syntax tree, wherein the text file comprises the parameter associated with the logic description. In some implementations, the IR data structure may be a FIRRTL data structure, and the RTL data structure may comprise Verilog. In some implementations, the method may include using the parameter when simulating the RTL data structure.

In a second aspect, the subject matter described in this specification can be embodied in an apparatus that includes: a memory; and a processor configured to execute instructions stored in the memory to: generate an integrated circuit design for an integrated circuit, wherein the integrated circuit design includes an instance of a module description that describes a functional operation of a module, and wherein the integrated circuit design is encoded in an intermediate representation (IR) data structure; receive a parameter comprising metadata associated with the instance; and compile the IR data structure to produce a register-transfer level (RTL) data structure, wherein the RTL data structure encodes a logic description associated with the instance, and wherein compiling the IR data structure comprises associating the parameter with the logic description. In some implementations, the instructions may include instructions to execute a compiler transformation and change the parameter based on the compiler transformation. In some implementations, the instructions may include instructions to receive an instance path associated with the parameter and use the instance path to associate the parameter with the logic description. In some implementations, the instructions may include instructions to receive a text file comprising the parameter associated with the instance and prepare an abstract syntax tree from the text file, wherein the abstract syntax tree is updated to associate the parameter with the logic description. In some implementations, the instructions may include instructions to use the parameter when simulating the RTL data structure.

In a third aspect, the subject matter described in this specification can be embodied in a non-transitory computer-readable storage medium that includes instructions that, when executed by a processor, causes the processor to: generate an integrated circuit design for an integrated circuit, wherein the integrated circuit design includes an instance of a module description that describes a functional operation of a module, and wherein the integrated circuit design is encoded in an intermediate representation (IR) data structure; receive a parameter comprising metadata associated with the instance; and compile the IR data structure to produce a register-transfer level (RTL) data structure, wherein the RTL data structure encodes a logic description associated with the instance, and wherein compiling the IR data structure comprises associating the parameter with the logic description. In some implementations, the instructions, when executed by the processor, further cause the processor to execute a compiler transformation and change the parameter based on the compiler transformation. In some implementations, the instructions, when executed by the processor, further cause the processor to receive an instance path associated with the parameter and use the instance path to associate the parameter with the logic description. In some implementations, the instructions, when executed by the processor, further cause the processor to receive a text file comprising the parameter associated with the instance and prepare an abstract syntax tree from the text file, wherein the abstract syntax tree is updated to associate the parameter with the logic description. In some implementations, the instructions, when executed by the processor, further cause the processor to use the parameter when simulating the RTL data structure.

While the disclosure has been described in connection with certain embodiments, it is to be understood that the disclosure is not to be limited to the disclosed embodiments but, on the contrary, is intended to cover various modifications and equivalent arrangements included within the scope of the appended claims, which scope is to be accorded the broadest interpretation so as to encompass all such modifications and equivalent structures.

What is claimed is:

1. A method comprising:
generating an integrated circuit design for an integrated circuit, wherein the integrated circuit design includes an instance of a module description that describes a functional operation of a module, and wherein the integrated circuit design is encoded in an intermediate representation (IR) data structure;
receiving a parameter comprising metadata associated with the instance; and
compiling the IR data structure to produce a register-transfer level (RTL) data structure, wherein the RTL data structure encodes a logic description associated with the instance, and wherein compiling the IR data structure comprises associating the parameter with the logic description such that the metadata is available to a tool that simulates or verifies the RTL data structure.

2. The method of claim 1, further comprising:
executing a compiler transformation; and
changing the parameter based on the compiler transformation.

3. The method of claim 1, wherein the parameter is at least one of:
a name associated with the instance;
a name associated with a connection to the instance; or
a memory address associated with the instance.

4. The method of claim 1, further comprising:
receiving an instance path associated with the parameter; and
using the instance path to associate the parameter with the logic description.

5. The method of claim 1, further comprising changing the parameter when compiling the IR data structure by at least one of:
changing a name associated with the instance;
changing a name associated with a connection to the instance; or
indicating a removal of a connection associated with the instance.

6. The method of claim 1, wherein the parameter is a first parameter, wherein the integrated circuit design includes a connection to the instance, wherein the RTL data structure encodes a node associated with the connection, and further comprising:
receiving a second parameter comprising metadata associated with the connection, wherein compiling the IR data structure includes:
associating the second parameter with the node.

7. The method of claim 1, further comprising:
receiving a text file comprising the parameter associated with the instance; and
preparing an abstract syntax tree from the text file, wherein the abstract syntax tree is updated to associate the parameter with the logic description.

8. The method of claim 1, further comprising:
preparing an abstract syntax tree, wherein the abstract syntax tree associates the parameter with the instance, and wherein the abstract syntax tree is updated to associate the parameter with the logic description; and
producing a text file from the abstract syntax tree, wherein the text file comprises the parameter associated with the logic description.

9. The method of claim 1, wherein the IR data structure is a flexible intermediate representation for register-transfer level (FIRRTL) data structure, and wherein the RTL data structure comprises Verilog.

10. The method of claim 1, further comprising:
using the parameter when simulating the RTL data structure.

11. An apparatus, comprising:
a memory; and
a processor configured to execute instructions stored in the memory to:
generate an integrated circuit design for an integrated circuit, wherein the integrated circuit design includes an instance of a module description that describes a functional operation of a module, and wherein the integrated circuit design is encoded in an intermediate representation (IR) data structure;
receive a parameter comprising metadata associated with the instance; and
compile the IR data structure to produce a register-transfer level (RTL) data structure, wherein the RTL data structure encodes a logic description associated with the instance, and wherein compiling the IR data structure comprises associating the parameter with the logic description such that the metadata is available to a tool that simulates or verifies the RTL data structure.

12. The apparatus of claim 11, wherein the instructions include instructions to:
execute a compiler transformation; and
change the parameter based on the compiler transformation.

13. The apparatus of claim 11, wherein the instructions include instructions to:
receive an instance path associated with the parameter; and
use the instance path to associate the parameter with the logic description.

14. The apparatus of claim 11, wherein the instructions include instructions to:
receive a text file comprising the parameter associated with the instance; and
prepare an abstract syntax tree from the text file, wherein the abstract syntax tree is updated to associate the parameter with the logic description.

15. The apparatus of claim 11, wherein the instructions include instructions to:
use the parameter when simulating the RTL data structure.

16. A non-transitory computer-readable storage medium that includes instructions that, when executed by a processor, causes the processor to:
generate an integrated circuit design for an integrated circuit, wherein the integrated circuit design includes an instance of a module description that describes a functional operation of a module, and wherein the integrated circuit design is encoded in an intermediate representation (IR) data structure;
receive a parameter comprising metadata associated with the instance; and
compile the IR data structure to produce a register-transfer level (RTL) data structure, wherein the RTL data structure encodes a logic description associated with the instance, and wherein compiling the IR data structure comprises associating the parameter with the logic description such that the metadata is available to a tool that simulates or verifies the RTL data structure.

17. The non-transitory computer-readable storage medium of claim 16, wherein the instructions, when executed by the processor, further cause the processor to:
execute a compiler transformation; and
change the parameter based on the compiler transformation.

18. The non-transitory computer-readable storage medium of claim 16, wherein the instructions, when executed by the processor, further cause the processor to:
receive an instance path associated with the parameter; and
use the instance path to associate the parameter with the logic description.

19. The non-transitory computer-readable storage medium of claim 16, wherein the instructions, when executed by the processor, further cause the processor to:
receive a text file comprising the parameter associated with the instance; and
prepare an abstract syntax tree from the text file, wherein the abstract syntax tree is updated to associate the parameter with the logic description.

20. The non-transitory computer-readable storage medium of claim 16, wherein the instructions, when executed by the processor, further cause the processor to:
use the parameter when simulating the RTL data structure.
